(19) United States
(12) Patent Application Publication
(10) Pub. No.: US 2007/0152071 A1
(43) Pub. Date: Jul. 5, 2007

(54) Package method for flash memory card and structure thereof

(75) Inventor: En-Min Jow, Hsinchu City (TW)

Correspondence Address: BACON & THOMAS, PLLC, 625 SLATERS LANE, FOURTH FLOOR, ALEXANDRIA, VA, 22314, US

(73) Assignee: En-Min JOW, Hsinchu City (TW)

(21) Appl. No.: 11/602,204

(22) Filed: Nov. 21, 2006

(30) Foreign Application Priority Data
Jan. 5, 2006 (TW) 95100500
Jun. 16, 2006 (TW) 95121679
Sep. 26, 2006 (TW) 95135543

(51) Int. Cl. G06K 19/06; H01L 23/02

(52) U.S. Cl. 235/492; 257/679

(57) ABSTRACT

A package method for a flash memory card and structure thereof is disclosed. A plurality of independent memory card module substrates are arranged on the substrate and those memory card module substrates are suspended and connecting with the substrate by a plurality of connecting bars. Chips are arranging on those memory card module substrates and the molding compound is utilizing to respectively cover chips, those memory card module substrates, wherein the molding compound is formed as a chamfered standard profile by performing a molding process with a upper molding substrate and a support substrate. Then punch, and grind the plurality of rugged bumps of those connecting bars to gain good cutting surface of the product and lower the cost.

### BACKGROUND OF THE INVENTION

1. Field of the Invention

The present invention generally relates to a semiconductor package technology, and more especially, relates to a package method for a flash memory card and the structure thereof.

2. Description of the Prior Art

Accordingly, the micro secure digital memory card (Micro SD card) is a light and handy, portable data storage device, it may use on different electronic apparatus, such as, personal computer, cell phone, digital camera . . . etc. As shown in FIG. 1A and FIG. 1B, illustrating the front view and the back view of Micro SD card respectively. The shape of Micro SD card 100 is multilateral and has a salient shape and a re-entrant shape 102 on one side. The prior cutting process of Micro SD card is to cut and separate the plurality of Micro SD card assemblies to a plurality of unitary assemblies.

Referring to FIG. 2, it is the front view diagram and illustrates the generally forming method of the unitary Micro SD card. To arrange the plurality of Micro SD card module substrates 120 on a substrate 110, after placing chips (not shown) on the proper location, then utilize the molding component 130 to cover the whole surface of the substrate 110, which includes the plurality of unitary Micro SD card module substrates 120. Wait until the molding compound 130 harden, exploiting the water jet or the laser-cutting machine (not shown) to separate a plurality of Micro SD card assemblies to the plurality of unitary Micro SD card 100 accurately. However, the laser-cutting machine and the water jet machine are very expensive equipments, the water jet machine even needs extra abrasives to achieve cutting purpose. Besides, no matter using laser or water jet method to process cutting, it must spend more time to calibrating the machine precisely and the cutting process is so slow. The productivity is lower relatively. The cutting surface is rough, the size is difficult to control and it easily causes the problem as plugging in or out.

FIG. 8A, FIG. 8B and FIG. 8C are the side view and the upward view of Micro SD card according to the prior art after the cutting process. Such as shown in FIG. 8A, the Micro SD card module substrates 120 is exposed at the lateral side of the Micro SD card 100. Hence, metal wire 122 on the Micro SD card module substrate 120 is also exposed so as to easily cause the pollution of the metal dust and the poor-contacting problem. The general solution to overcome this problem is to open the window at the edge of the solder mask, then to etch back to remove the metal wire, and next to perform the prior package process. However, such as shown in FIG. 8B and FIG. 8C, after chamfering the Micro SD card 100, it cannot use the same solution to overcome the problem that the metal wire 122 on the Micro SD card module substrate 120 is exposed.

In order to achieve the goal that Micro SD card has no rough surface after cutting, the expensive cutting equipment, the low productivity, and the exorbitant cost are the part portion of blemish in an otherwise perfect thing. Therefore, these are urgent issues that enterprises need to overcome currently.

### SUMMARY OF THE INVENTION

According to the issue mentioned previously, the present invention provides a package method for a flash memory card and the structure thereof.

It is an object of the present invention to provide a package method for a flash memory card and the structure thereof, to arrange a plurality of memory card module substrates and a plurality of connecting bars on a substrate. When processing the molding steps, just needs injecting the molding compound into the memory card module substrate instead of injecting the molding compound into the whole substrate. As this result, the present invention avoids the waste of the molding compound and reduces the cost of the molding compound.

Another object of the present invention is to provide a package method for a flash memory card and the structure thereof, to arrange a plurality of memory card module substrates and a plurality of connecting bars on a substrate. When processing the molding steps, just needs injecting the molding compound into the memory card module substrate instead of injecting the molding compound into the whole substrate, wherein the cover area of the molding component is larger than the area of the memory card module substrate so as the present invention can design the specific shape with accurately dimension and have a stable manufacturing process without cutting the large area.

It is an object of the present invention to provide a package method for a flash memory card and the structure thereof, exploiting the punch method to separate the plurality of connecting bars arranged on the substrate. The punch method can separate the substrate and the memory card package directly, without using the expensive cutting equipment (such as laser cutting machine or water jet) to process the cutting. The present invention can reduce the cost of the production equipment and also raise the productivity.

Another object of this invention is to provide a package method for a flash memory card and the structure thereof, exploiting the punch device to go though the package cutting process. Regarding the cutting speed of the punch device is faster than the traditional laser-cutting machine or water-jet machine. The present invention can raise the productivity due to the short cutting processing time.

Another object of this invention is to provide a package method for a flash memory card and the structure thereof. A plurality of connecting bars are designed on the substrate to avoid the molding compound peeling or the package cracks due to the punch location excessively close to the package when punching. It can raise the production yield furthermore.

Another object of the present invention is to provide a package method for a flash memory card and the structure thereof. Accurately polish the extra and unnecessary molding compound, which caused by the punch process, to achieve the goal that package has no rough surface after punching.

One object of the present invention provides a package method for a flash memory card and the structure thereof, the molding component can directly mold as a chamfered standard shape to simplify the chamfering step. Wherein, the cover area of the molding component is larger than the area of the memory card module substrate, so as the metal wire on the memory card module substrate would not be exposed at the sidewall of the memory card module substrate to cause the contamination of the metal dust or the poor-connect.

Accordingly, one embodiment of the present invention provides a package method for a flash memory card includes: providing a substrate with a plurality of memory card module substrates arranged thereon, wherein each of memory card module substrates is linking with the substrate with a plurality of connecting bars; utilizing a molding component to respectively cover the memory card module substrates and expose a portion of connecting bars; cutting the connecting bars to obtain a plurality of memory card packages; and smoothing the connecting bars protruding from each of memory card packages.

Another embodiment of the present invention provides a package structure for a flash memory card includes: a substrate with a plurality of memory card module substrates arranged thereon, wherein each of memory card module substrates is linking with the substrate with a plurality of connecting bars; and a molding component to respectively cover the memory card module substrates to expose a portion of connecting bars.

The other embodiment of the present invention provides a package structure for a flash memory card includes: a memory card module substrate having a plurality of connecting bars to link with a substrate; and a molding component to cover the memory card module substrate and the connecting bars.

### BRIEF DESCRIPTION OF THE DRAWINGS

The foregoing aspects and many of the accompanying advantages of this invention will become more readily appreciated as the same becomes better understood by reference to the following detailed description, when taken in conjunction with the accompanying drawings, wherein:

FIG. 1A and FIG. 1B illustrate the front view and the back view of Micro SD card respectively;

FIG. 2 illustrates the generally forming method of the unitary Micro SD card;

FIG. 3A, FIG. 3B and FIG. 3C illustrate an embodiment of the present invention;

FIG. 3D illustrates the side view of AA′ cross-section line of FIG. 3C;

FIG. 4A, FIG. 4B, FIG. 4C and FIG. 4D illustrate the slightly modification smoothing steps in accordance with an embodiment of the present invention;

FIG. 5 is a flow chart illustrating an embodiment of the present invention;

FIG. 6 illustrates the shape of the connecting bars, the distribution of the connecting bars, and the mount of the connecting bars in accordance with different embodiments of the present invention;

FIG. 7 illustrates an embodiment of the present invention;

FIG. 8A, FIG. 8B and FIG. 8C are the side view and the upward view of Micro SD card according to the prior art;

FIG. 9 is a flow chart illustrating an embodiment of the present invention; and

FIG. 10A, FIG. 10B and FIG. 10C illustrate an embodiment of the present invention.

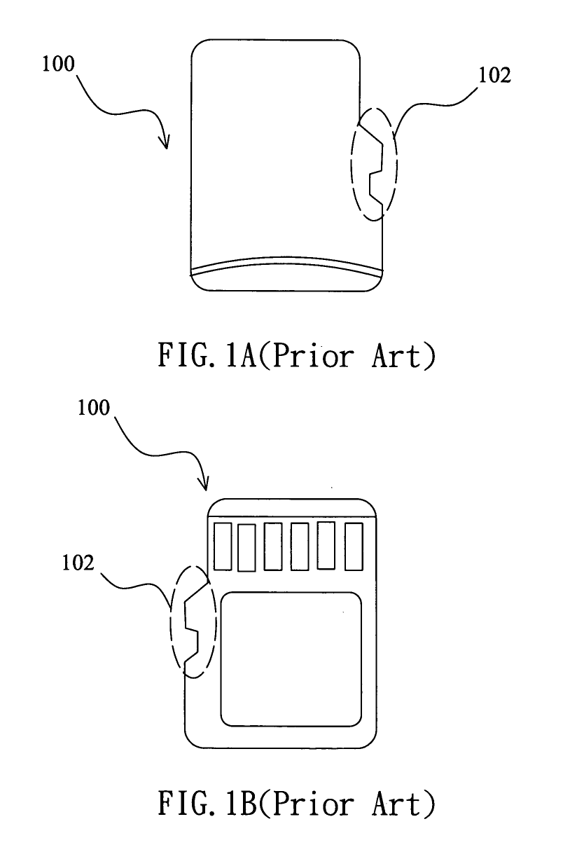

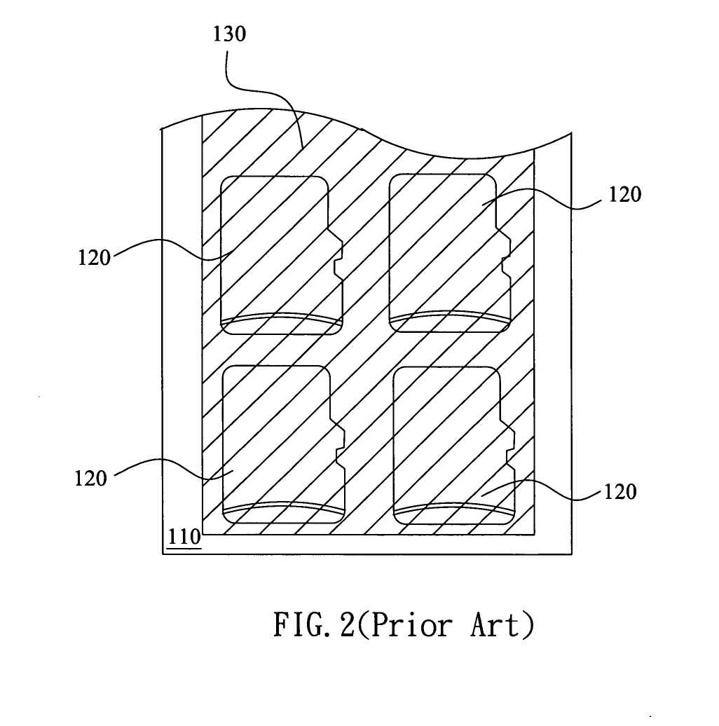

### DESCRIPTION OF THE PREFERRED EMBODIMENT

To explain a package method for a flash memory card and the structure thereof with preferred embodiments of the present invention;

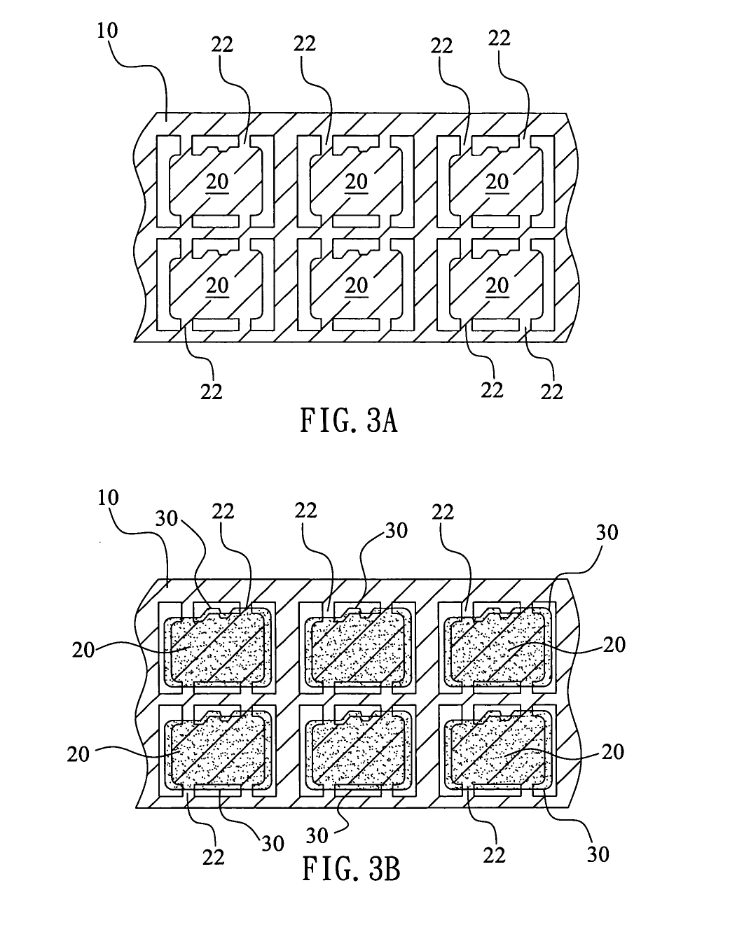

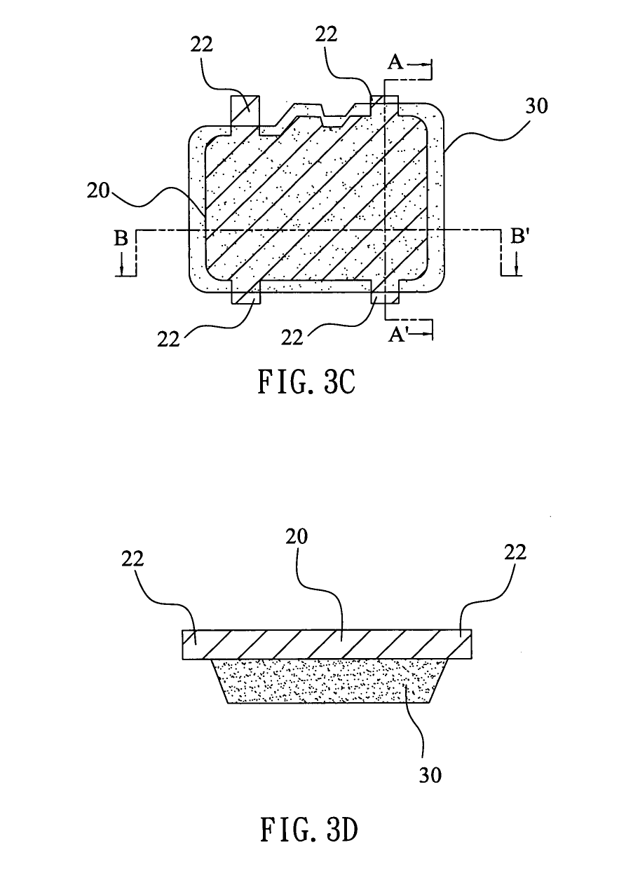

First, referring to FIG. 3A, illustrating the substrate design in accordance with an embodiment of the present invention. In the present embodiment, there are a plurality of flash memory card module substrates 20 arranged on a substrate 10. Each of those flash memory card module substrates 20 is independently linking with the substrate 10 with connecting bars 22. Among those connecting bars 22 is the hollow portion of the substrate 10. Referring to FIG. 3B, after placing the chip (not shown) on the proper location of the flash memory card module substrate 20, a molding compound 30, which made of epoxy, is covering each flash memory card module substrate 20 to expose a portion of connecting bars 22. Wherein the geometric figure formed by the molding compound 30 is similar to the flash memory card module substrate 20 but the cover area is a little bit larger than the size of the flash memory card module substrate 20. Besides, in order to avoid the molding compound squeeze out while molding, it may paste tapes on the surface of the cavity (not shown) and let the substrate 10, the flash memory card module substrate 20 and the cavity (not shown) close together and the molding compound 30 will not squeeze out. Then, a punch device is utilized to perform the singulation step; those connecting bars 22 are dismembered to form a plurality of memory card packages.

Please refer to FIG. 3C, in order to avoid the molding compound 30 peeling or the memory card package cracks due to the punch location excessively close to the memory card package while punching, there is a little interval between the punch location and the memory card package. Therefore, the memory card package after punching has a plurality of bumps, the side view of AA′ cross-section line is shown in FIG. 3D. These bumps are the part portion of the original connecting bars 22 of the substrate 10. Referring to FIG. 3C, in one embodiment, the package structure for a flash memory card of the present includes a memory card module substrate 20 having a plurality of connecting bars 22 to link with a substrate (not shown in Figure); and a molding component 30 to cover the memory card module substrate 20 and those connecting bars 22. Wherein, a portion of connecting bars 22 is exposed to the molding component 30.

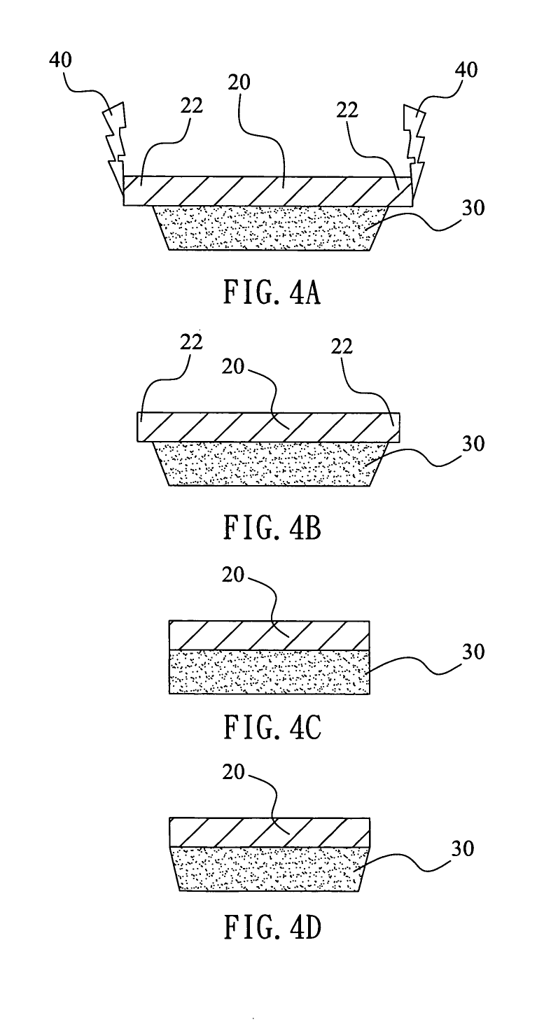

Next, FIG. 4A, FIG. 4B, FIG. 4C and FIG. 4D illustrating the slightly modification smoothing steps in accordance with an embodiment of the present invention, it can use the saw-tooth tool 40 to polish the extra, unnecessary molding compound. In one embodiment, it may use several steps to grind the detail portion by different polish tools. For example, in the beginning of the slightly modification smoothing steps, it may choose rough pellet or surface tools to grind, polish those bumps of connecting bars 22 promptly. Please refer to FIG. 4B, until those bumps almost disappear, now may choose smoother pellet or surface tools to slightly modify smoothing the whole edge of the memory card package. Referring to FIG. 4C, start the chamfer steps to form the memory card package with the international standard size and shape, after the whole edge of the memory card package become smoothly. It is to be understood, the chamfer step can also separate to several steps to process. After punching, the size of the memory card package will become international standard size by using the slightly modification smoothing steps. By the way, the slightly modification smoothing tool not limited on the saw-tooth tool 40, it may be suitable for using the dice (which made of diamond and used to dicing the wafer) to dice the tiny bump and the bump which very close to the memory card package. Or it may choose the high rotating speed router (which used to route and to form the print circuit board) to remove those bumps to smooth surface.

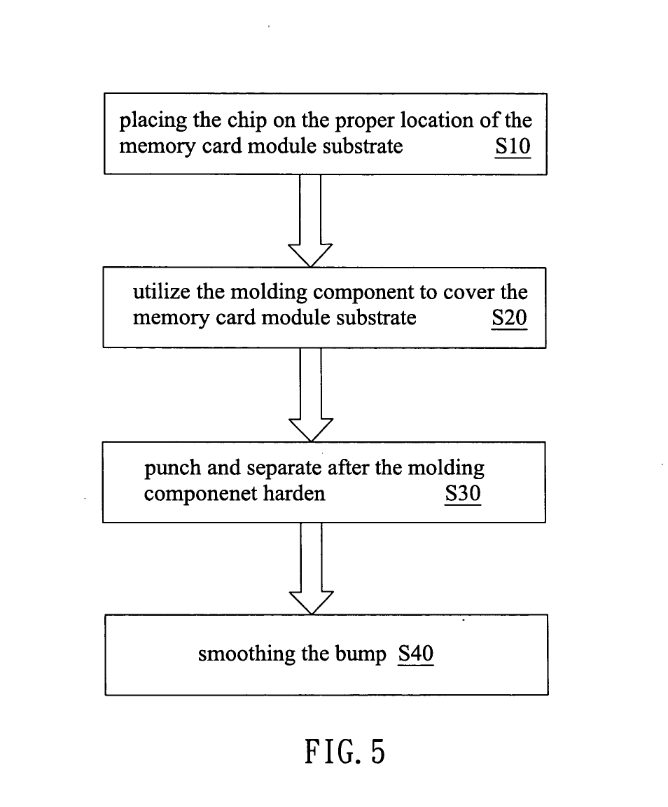

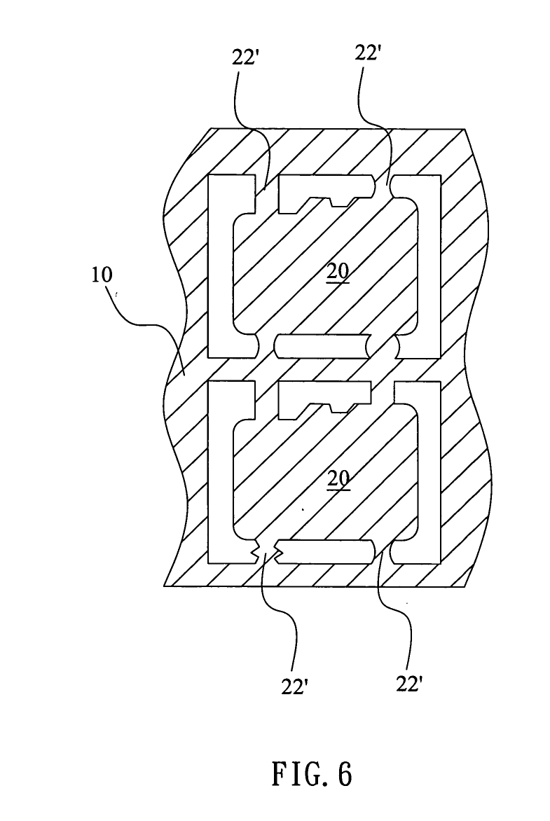

FIG. 5. is a flow chart illustrating an embodiment of the present invention. Simultaneously referring to FIG. 3B and FIG. 5, providing a substrate 10 having a plurality of memory card module substrates 20, wherein those memory card module substrates 20 are linking with the substrate 10 with a plurality of connecting bars 22 and placing the chip on the proper location of each of those memory card module substrates 20 (step 10). And then utilize the molding compound 30 to cover the memory card module substrates 20 (step 20) to expose a portion of connecting bars 22. While the package process completed and the molding component 30 harden, start punch and separate those memory card packages (step 30) and then slightly modify smoothing the bump at the edge of the memory card package step by step (step 40), wherein the slightly modification smoothing step includes grind, polish and chamfer.

FIG. 6 is illustrating the shape of the connecting bars 22′, the distribution of the connecting bars 22′, and the mount of the connecting bars 22 in accordance with different embodiments of the present invention. Those connecting bars 22′ are used to connect those memory card module substrates 20 and not limited as shown in this embodiment of the present invention. The location, the shape, and the size of the connecting bars 22′ may be variable, just depend on the different arrangements of memory card module substrates 20 on the substrate 10. The shape of those connecting bars is in polygon, bar, round shape, or multi-radian shape.

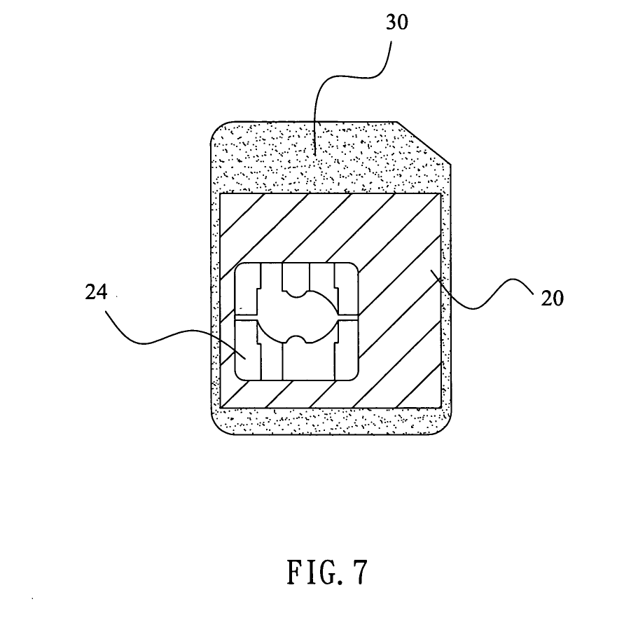

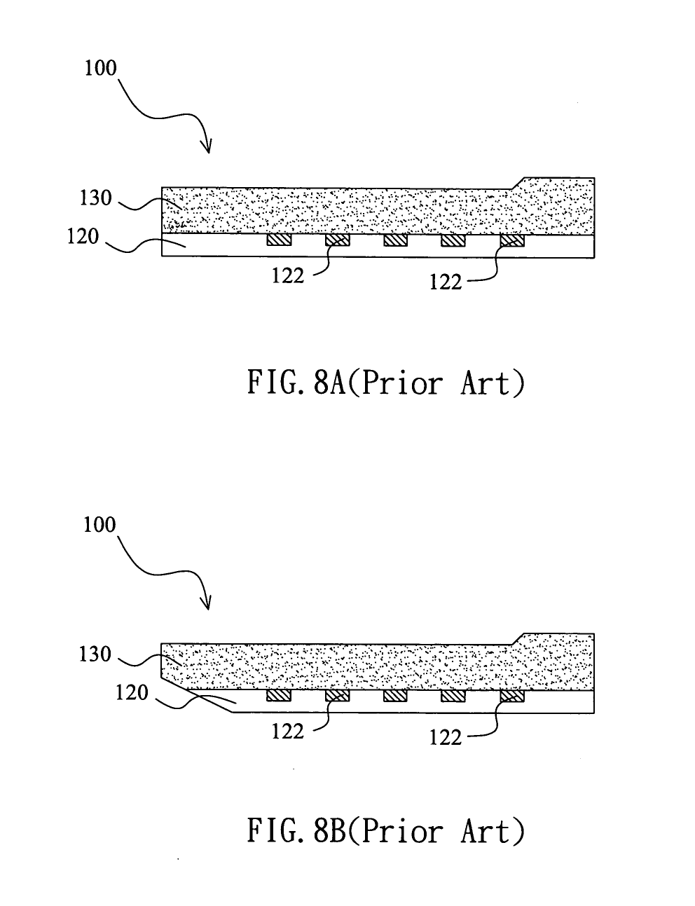

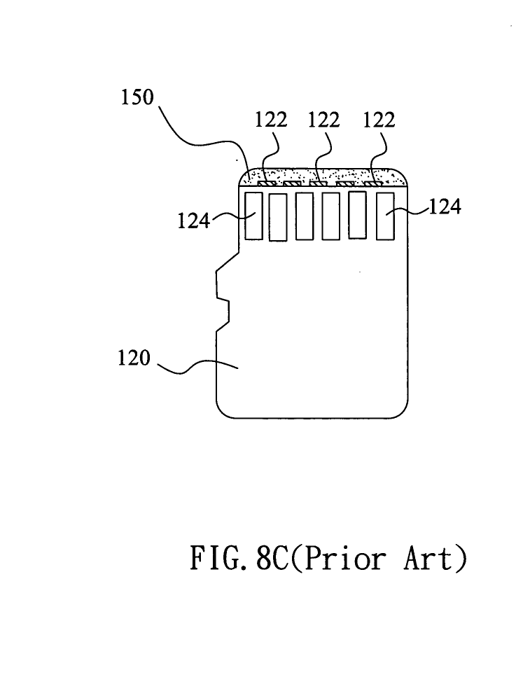

Referring to FIG. 7, in the present embodiment, the cover area of the molding component 30 of the flash memory SIM card is larger than the memory card module substrate 20, wherein there are golden fingers 24 arranged on the memory card module substrate 20 at the back side of the flash memory SIM card. However, the present invention can apply to the micro SD memory card or the package method of the micro SD memory card, but not limited herein. The present invention can apply to kinds of the package of the flash memory card.

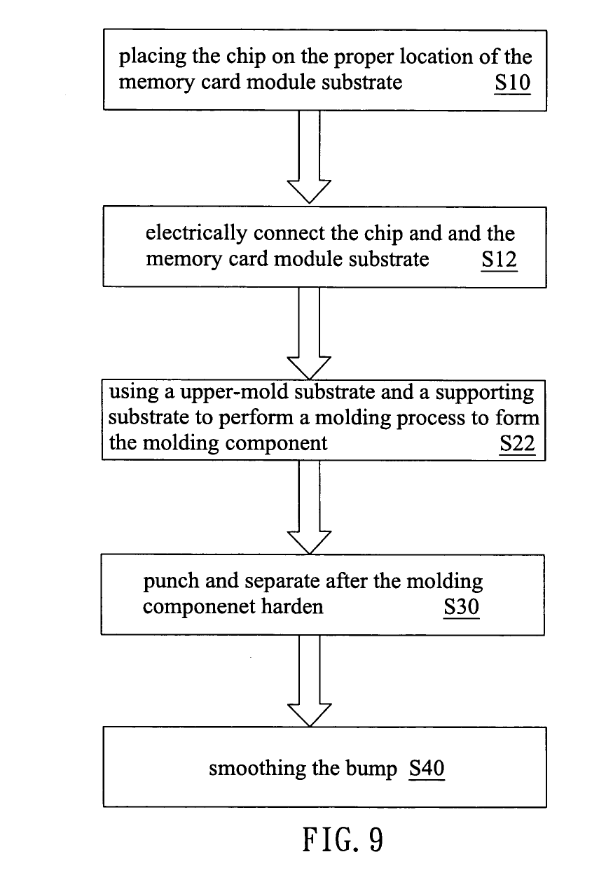

Besides, referring to FIG. 9 and FIG. 3B, first providing a substrate 10 having a plurality of memory card module substrates 20, wherein those memory card module substrates 20 are linking with the substrate 10 with a plurality of connecting bars 22 and placing the chip (not shown in the figure) on the proper location of each of those memory card module substrates 20 (step 10). Next, electrically connect the chip and memory card module substrate 20 (step 12), and then utilize the molding compound 30 to respectively cover the chip and the upper surface of the memory card module substrates 20 to expose the lower surface of the memory card module substrate 20 and a portion of connecting bars 22 by using a upper-mold substrate and a supporting substrate to perform a molding process to form the molding component (step 22). Wherein the molding component is directly mold as a chamfered standard profile. While the package process completed and the molding component 30 harden, start punch and separate those memory card packages (step 30) and then slightly modify smoothing the bump at the edge of the memory card package step by step (step 40), wherein the slightly modification smoothing step includes grind and polish. Owing to the molding component is directly mold as a chamfered standard profile, in the present invention; it is not necessary to perform the chamfer step to each memory card package.

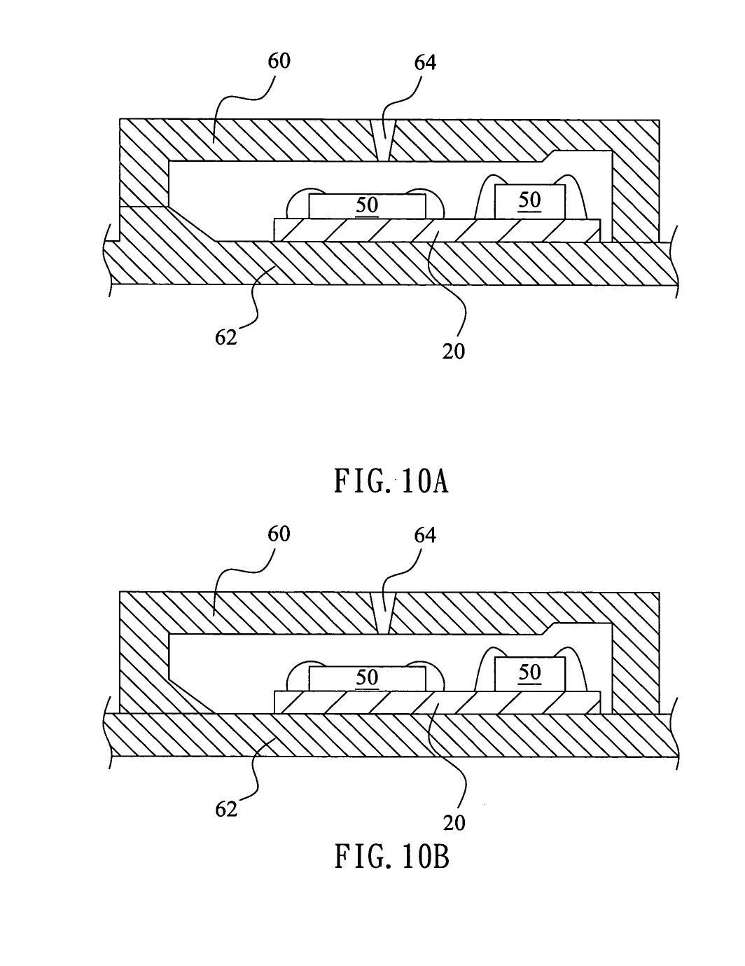

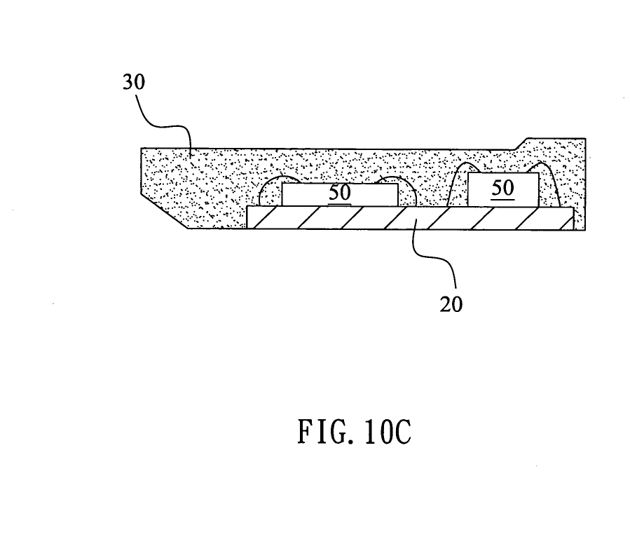

Following the forgoing description, referring to FIG. 10A, FIG. 10B and FIG. 10C, in the present embodiment, a upper-substrate 60 and a supporting substrate 62 are utilized to perform the molding process to form the molding component 30. The upper-mold substrate 60 has a through hole 64 thereon for injecting the molding material. The supporting substrate 62 provides the supporting effect and can be replaced with a bearing plate or other base substrate. The molding component 30 is respectively cover the chip 50 and the upper surface of the memory card module substrate 20 and to expose the lower surface of the memory card module substrate 20 and a portion of connecting bars (not shown in the figure). In the present invention, the chamfered standard profile of the molding component 30 is modeled the profile by the upper-mold substrate 60, such as shown in FIG. 10B. However, the present invention is not limited herein, the chamfered standard profile of the molding component 30 can be also modeled the profile by the supporting substrate 62, such as shown in FIG. 10A.

Please referring to FIG. 10C, in the package structure of the present embodiment, at least a chip 50 is arranged on the memory card module substrate 20, the chip 50 is electrically connecting with the memory card module substrate 20 by wire-bonding or other ways. A molding component 30 is cover the chip 50 and the upper surface of the memory card module substrate 20 to expose the lower surface of the memory card module substrate 20. The molding component 30 is directly mold as a chamfered standard profile. Besides, not shown in the figure, whether the molding component 30 covers or not covers connecting bars depending on the process requirement. There is a golden finger (not shown in the figure) arranged on the upper surface of the memory card module substrate 20.

Accordingly, one of features of the present invention is to arrange a plurality of memory card module substrate linking with the substrate with a plurality of connecting bars. It utilizes the punch method to separate connecting bars to form a plurality of memory card packages. Due to the buffer space between the connecting bars and the memory card package, it can avoid the molding compound peeling or the package cracks due to the punch location excessively close to the package when punching so as to raise the production yield. In the molding step, the molding component would not completely cover the whole substrate but only perform the molding step on the memory card module substrate so as can reduce the cost of the molding material. Furthermore, the punch device is cheaper and faster than the traditional laser-cutting machine or water-jet machine so as to reduce the cost and to raises the productivity.

To sum up the forgoing, the present invention utilizes the arrangement of a plurality of memory card module substrates and a plurality of connecting bars on a substrate. When processing the molding steps, just needs injecting the molding compound into the memory card module substrate instead of injecting the molding compound into the whole substrate. As this result, the present invention avoids the waste of the molding compound and reduces the cost of the molding compound. Wherein, the cover area of the molding component is larger than the area of the memory card module substrate so as the present invention can design the specific shape with accurately dimension and have a stable manufacturing process without cutting the large area. The present invention utilizes the punch method to separate the plurality of connecting bars arranged on the substrate. The punch method can separate the substrate and the memory card package directly, without using the expensive cutting equipment (such as laser cutting machine or water jet) to process the cutting. The present invention can reduce the cost of the production equipment and also raises the productivity. Hence, the present invention utilizes the punch device to go though the package cutting process. Regarding the cutting speed of the punch device is faster than the traditional laser-cutting machine or water-jet machine. The present invention can raise the productivity due to the short cutting processing time. A plurality of connecting bars are designed on the substrate to avoid the molding compound peeling or the package cracks due to the punch location excessively close to the package when punching. It can raise the production yield furthermore. Accurately polish the extra and unnecessary molding compound, which caused by the punch process, to achieve the goal that package has no rough surface after punching. In the present invention, the molding component can directly mold as a chamfered standard shape to simplify the chamfering step. Wherein, the cover area of the molding component is larger than the area of the memory card module substrate, so as the metal wire on the memory card module substrate would not be exposed at the sidewall of the memory card module substrate to cause the contamination of the metal dust or the poor-connect.

While the present invention is susceptible to various modifications and alternative forms, a specific example thereof has been shown in the drawings and is herein described in detail. It should be understood, however, that the invention is not to be limited to the particular form disclosed, but to the contrary, the invention is to cover all modifications, equivalents, and alternatives falling within the spirit and scope of the appended claims.

What is claimed is:

1. A package method for a flash memory card comprising the following steps:
providing a substrate with a plurality of memory card module substrates arranged thereon, wherein each of said memory card module substrates is linking with said substrate with a plurality of connecting bars;
utilizing a molding component to respectively cover said memory card module substrates and expose a portion of said connecting bars;
cutting said connecting bars to obtain a plurality of memory card packages; and
smoothing said connecting bars protruding from each of said memory card packages.

2. The package method for a flash memory card according to claim 1, wherein said molding component is made of epoxy.

3. The package method for a flash memory card according to claim 1, wherein a punch device is utilized to cut said connecting bars.

4. The package method for a flash memory card according to claim 1, wherein a saw-tooth device is utilized to remove said connecting bars protruding from each of said memory card packages.

5. The package method for a flash memory card according to claim 1, wherein a chip cutting device is utilized to polish said connecting bars protruding from each of said memory card packages.

6. The package method for a flash memory card according to claim 1, wherein a router is utilized to route said connecting bars protruding from each of said memory card packages.

7. The package method for a flash memory card according to claim 1, the shape of said connecting bars is in polygon, bar, round shape, or multi-radian shape.

8. The package method for a flash memory card according to claim 1, further comprising a step of utilizing a upper-mold substrate and a supporting substrate to perform a molding process to form said molding component.

9. The package method for a flash memory card according to claim 8, wherein said molding component is directly molding as the standard chamfered external dimension and feature.

10. The package method for a flash memory card according to claim 1, wherein a golden finger is arranged on said lower surface of said memory card module substrate.

11. The package method for a flash memory card according to claim 1, further comprising the step of respectively fixing a chip on each of said memory card module substrates, wherein said chip is electrically connecting to each of said memory card module substrates.

12. The package method for a flash memory card according to claim 1, wherein said molding component respectively covers said chip and a upper surface of said memory card module substrate to expose a lower surface of said memory card module substrate and a portion of said connecting bars.

13. A package structure for a flash memory card comprising:
a substrate with a plurality of memory card module substrates arranged thereon, wherein each of said memory card module substrates is linking with said substrate with a plurality of connecting bars; and
a molding component to respectively cover said memory card module substrates to expose a portion of said connecting bars.

14. The package structure for a flash memory card according to claim 13, wherein said molding component is made of epoxy.

15. The package structure for a flash memory card according to claim 13, wherein the shape of said connecting bars is in polygon, bar, round shape, or multi-radian shape.

16. The package structure for a flash memory card according to claim 13, wherein a chip is fixed on each of said memory card module substrates and electrically connecting to each of said memory card module substrates.

17. The package structure for a flash memory card according to claim 13, wherein a cover area of said molding component respectively covering each said memory card module substrate is larger than the area of each said memory card module substrate.

18. The package structure for a flash memory card according to claim 13, wherein said molding component is formed by an injection process using a upper-mold substrate and a support substrate.

19. The package structure for a flash memory card according to claim 18, wherein said molding component is directly molding as the standard chamfered external dimension and feature.

20. The package structure for a flash memory card according to claim 13, wherein a golden finger is arranged on the lower surface of said memory card module substrate.

21. The package structure for a flash memory card according to claim 13, wherein said molding component respectively covers said chip and an upper surface of said memory card module substrate to expose a lower surface of said memory card module substrate and a portion of said connecting bars.

22. A package structure for a flash memory card comprising:
a memory card module substrate having a plurality of connecting bars to link with a substrate; and
a molding component to cover said memory card module substrate and said connecting bars.

23. The package structure for a flash memory card according to claim 22, wherein a portion of said connecting bars is exposed to said molding component.

24. The package structure for a flash memory card according to claim 22, wherein said molding component is made of epoxy.

25. The package method for a flash memory card according to claim 22, wherein the shape of said connecting bars is in polygon, bar, round shape, or multi-radian shape.

26. The package structure for a flash memory card according to claim 22, wherein a chip is fixed on each of said memory card module substrates.

27. The package structure for a flash memory card according to claim 22, wherein a cover area of said molding component respectively covering each said memory card module substrate is larger than the area of each said memory card module substrate.

28. The package structure for a flash memory card according to claim 22, wherein said molding component is formed by an injection process using an upper-mold substrate and a support substrate.

29. The package structure for a flash memory card according to claim 28, wherein said molding component is directly molding as the standard chamfered external dimension and feature.

30. The package structure for a flash memory card according to claim 22, wherein a golden finger is arranged on said lower surface of said memory card module substrate.

31. The package structure for a flash memory card according to claim 22, wherein a portion of said connecting bars is exposed to said molding component.

32. The package structure for a flash memory card according to claim 22, further comprising a chip arranged on said memory card module substrate and electrically connecting with said memory card module substrate.

33. The package structure for a flash memory card according to claim 22, wherein said molding component covers said chip, an upper surface of said memory card module substrate and said connecting bars to expose a lower surface of said memory card module substrate.
